(19) United States
(12) Patent Application Publication
(10) Pub. No.: US 2026/0040963 A1
(43) Pub. Date: Feb. 5, 2026

(54) SEMICONDUCTOR PACKAGES WITH SOLDER JOINT PILLARS

(71) Applicant: TEXAS INSTRUMENTS INCORPORATED, Dallas, TX (US)

(72) Inventors: Hsuan Lien CHOU, New Taipei City (TW); Fu Kang LEE, New Taipei City (TW); Kuan Ting CHEN, New Taipei City (TW)

(21) Appl. No.: 18/790,721

(22) Filed: Jul. 31, 2024

(51) Int. Cl. H01L 23/495; H01L 21/56; H01L 21/60; H01L 23/31; H01L 23/498

(52) U.S. Cl. CPC H01L 23/4952; H01L 21/563; H01L 21/565; H01L 21/60; H01L 23/3114; H01L 23/49534; H01L 23/49822; H01L 2021/6024

(57) ABSTRACT

In examples, a semiconductor package includes a solder joint pillar within a solder joint. The solder joint couples various structures of the semiconductor package.

### BACKGROUND

Semiconductor wafers are circular pieces of semiconductor material, such as silicon, that are used to manufacture semiconductor chips. Generally, complex manufacturing processes are used to form numerous integrated circuits on a single wafer. The formation of such circuits on a wafer is called fabrication. After wafer fabrication, the wafer is cut into multiple pieces, called semiconductor dies, with each die containing one of the circuits. The cutting, or sawing, of the wafer into individual dies is called singulation. An individual die is then coupled to a die pad and to conductive terminals, sometimes called “leads.” The resulting structure is subsequently covered with a mold compound to produce a package.

### SUMMARY

In examples, a semiconductor package comprises a semiconductor die having a device side in which circuitry is formed, and a multi-layer substrate having multiple metal layers and a build-up film in between and contacting the multiple metal layers, where the device side of the semiconductor die is coupled to at least one of the multiple metal layers of the multi-layer substrate. The package includes a first solder joint electrically connected to the device side of the semiconductor die via the multi-layer substrate, and a gullwing-shaped first conductive terminal coupled to the first solder joint, where the first conductive terminal has a first conductive terminal surface including a first metal pillar covered by the first solder joint. The package includes a second solder joint electrically connected to the device side of the semiconductor die via the multi-layer substrate. The package includes a gullwing-shaped second conductive terminal coupled to the second solder joint, the second conductive terminal having first and second segments, the first segment including a second conductive terminal surface comprising a second metal pillar covered by the second solder joint, and the second segment extending approximately parallel to the first conductive terminal, the second metal pillar coinciding with a vertical plane in which the first conductive terminal sits, the first and second segments coupled by a curved segment that lies in a horizontal plane approximately orthogonal to the vertical plane. The package includes a mold compound covering the semiconductor die, the first and second solder joints, and the first and second conductive terminals, the first and second conductive terminals extending outside of the mold compound through a surface of the mold compound.

In examples, a method for manufacturing a semiconductor package comprises applying solder to a metal pillar, the metal pillar extending away from a conductive terminal surface of a conductive terminal in a lead frame in a direction approximately orthogonal to the conductive terminal surface; contacting a first metal layer of a multi-layer substrate to the solder, the multi-layer substrate including a second metal layer above the first metal layer and further including a build-up film in between the first and second metal layers; and reflowing the solder to form a solder joint covering the metal pillar. The method also comprises coupling a device side of a semiconductor die to the second metal layer of the multi-layer substrate; covering the semiconductor die, the multi-layer substrate, the solder joint, and the conductive terminal with a mold compound, the conductive terminal extending through a surface of the mold compound to an exterior of the mold compound; and detaching the conductive terminal from the lead frame to form the semiconductor package.

### BRIEF DESCRIPTION OF THE DRAWINGS

FIGS. 1A-IC are profile cross-sectional, top-down, and perspective views of a semiconductor package with solder joint pillars, in accordance with various examples.

FIGS. 2A-2G2 are perspective and profile cross-sectional views of conductive terminals in a semiconductor package with solder joint pillars, in accordance with various examples.

FIG. 3 is a flow diagram of a method for manufacturing a semiconductor package having solder joint pillars, in accordance with various examples.

FIGS. 4A1-4G3 are a process flow for manufacturing a semiconductor package having solder joint pillars, in accordance with various examples.

FIGS. 5A-5C are profile cross-sectional, top-down, and perspective views of a semiconductor package with solder joint pillars, in accordance with various examples.

### DETAILED DESCRIPTION

Some semiconductor packages include multiple different types of materials with differing coefficients of thermal expansion (CTEs). For example, a single semiconductor package may include a copper lead frame, a solder joint that contacts the copper lead frame, a copper terminal (e.g., extending from a substrate in the semiconductor package) that contacts the solder joint, a build-up film (ABF) that contacts the copper terminal and the copper terminal, and a mold compound that contacts the ABF, the solder joint, and the lead frame. These materials may converge at the periphery of the solder joint, and because these components have varying CTEs, temperature cycling processes can cause the materials to separate due to the shear stresses experienced at the convergence point at the solder joint periphery. For example, the solder joints may peel off during a temperature cycling process. This phenomenon is a device failure that significantly reduces manufacturing yield and efficiency, and substantially increases manufacturing costs.

Furthermore, down set leads (e.g., the bending of leads) create areas of concentrated mechanical stress. These concentrated areas of stress can make the interfaces between different materials even more susceptible to delamination, particularly during thermal cycling. Further still, the down set lead configuration may complicate the application of adhesive materials or mold compounds, which in turn increases delamination risk.

These problems are further exacerbated by substrates that may be included in the package. For example, a substrate may be useful to couple one or more semiconductor dies to leads (or conductive terminals) of the package. If the substrate is relatively heavy, the weight of the substrate causes additional stress that makes the material interfaces described above even more vulnerable to delamination.

This disclosure describes various examples of semiconductor packages that include solder joints having solder joint pillars embedded therein. The solder joint pillars may be formed on any surface in the semiconductor package on which a solder joint will be formed. Each solder joint is formed to cover one or more solder joint pillars, although in at least some examples, each solder joint covers only a single solder joint pillar. A solder joint pillar increases the surface area to which the respective solder joint is coupled, thereby increasing adhesion strength between the solder joint and the solder joint pillar and decreasing the risk of peeling during temperature cycling (or during field deployment) due to mismatched CTEs between various materials in the package. For similar reasons, shear stress is also reduced. Further, the solder joint pillar 214, 216 operates as an anchor that mitigates distortion of the solder joint 106 during temperature cycling. By reducing shear stress and solder joint distortion, the risk of solder joint peeling is significantly reduced, thereby substantially increasing manufacturing yield and efficiency, and lowering manufacturing costs.

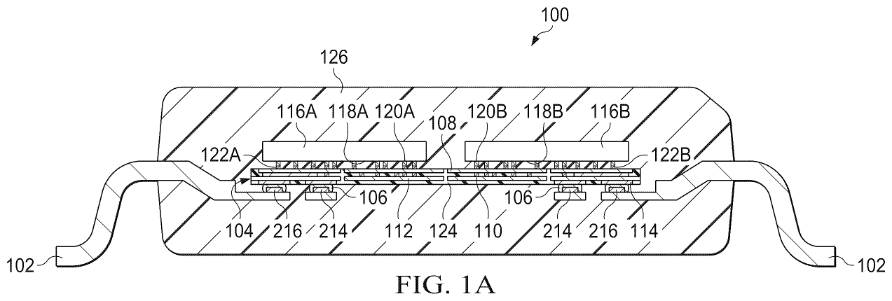

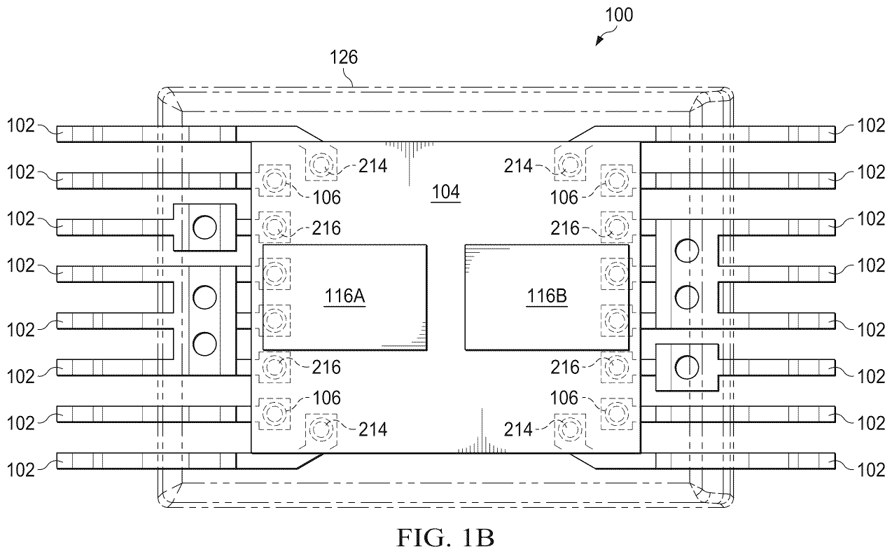

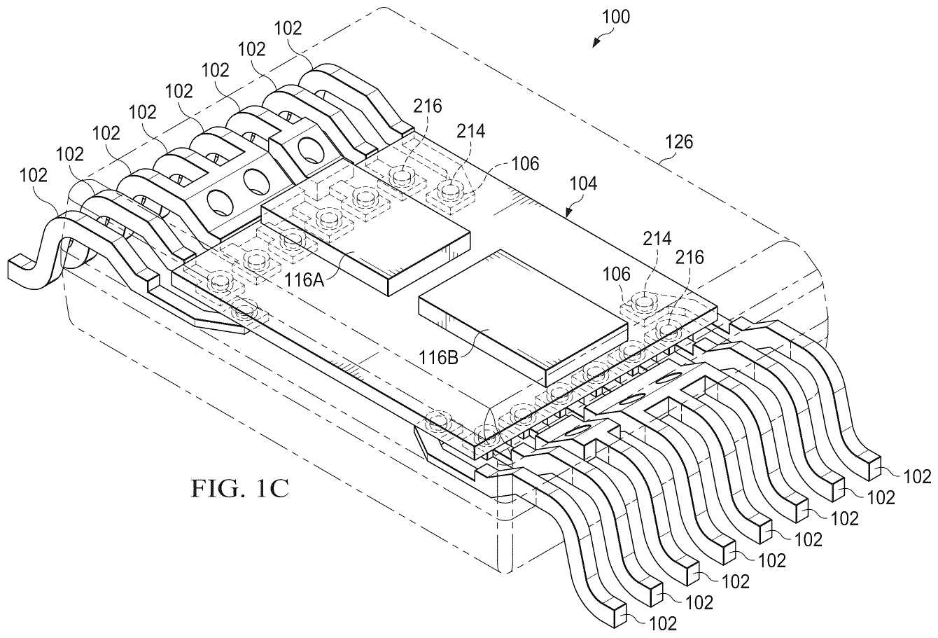

FIGS. 1A-IC are profile cross-sectional, top-down, and perspective views of a semiconductor package with solder joint pillars, in accordance with various examples. Specifically, FIG. 1A is a profile, cross-sectional view of a semiconductor package 100, which in various examples includes multiple conductive terminals 102 and a multi-layer substrate 104 coupled to the multiple conductive terminals 102 by way of solder joints 106. A multi-layer substrate is defined as a component of a semiconductor package (e.g., the semiconductor package 100), where the component includes multiple metal layers formed by electroplating and that further includes a dielectric such as a mold compound or film (e.g., AJINOMOTO® build-up film (ABF)) filling spaces between and around the multiple metal layers. The multiple metal layers form a network to route signals and/or power between various locations within the semiconductor package 100. The multi-layer substrate 104 differs from a printed circuit board (PCB) because the multi-layer substrate is within the semiconductor package 100, whereas the PCB is outside the semiconductor package 100. The multi-layer substrate 104 includes multiple metal layers that are separated by a solid, tangible dielectric, whereas the PCB may contain multiple layers of printed circuit board that may not be separated by a dielectric material other than air.

Accordingly, the multi-layer substrate 104 includes metal layers 108 and 112 connected by vias 110. The multi-layer substrate 104 may further include vias 114 to couple the metal layer 112 to electrically conductive components outside of the multi-layer substrate 104. In examples, the multi-layer substrate 104 includes additional metal layers coupled to other metal layers (e.g., metal layers 108, 112, or other metal layers) by way of one or more vias. Together, the various metal layers and vias in the multi-layer substrate 104 (e.g., the metal layers 108, 112 and the vias 110, 114) form a network of metal layers that facilitate the provision of electrical signals between the opposing top and bottom surfaces of the multi-layer substrate 104. The specific topography of the network of metal layers may be application-dependent. A film 124 (e.g., ABF) covers the metal layers 108, 112 and the vias 110, 114, as shown.

The multi-layer substrate 104 (which may be referred to herein as a “routable lead frame” (RLF)) may be manufactured by any suitable process. In some examples, the multi-layer substrate 104 is manufactured by an iterative process in which a first metal layer is plated (e.g., electroplated) on a base layer, and then a film (e.g., ABF) is deposited and grinded (e.g., thinned), followed by the formation of a second metal layer and the deposition and grinding of additional film material (e.g., ABF), and so on. Vias may be formed by plating concurrently with each metal layer, or alternatively, vias may be formed by plating in between successive metal layers.

The semiconductor package 100 may include multiple semiconductor dies, such as semiconductor dies 116A, 116B. The semiconductor dies 116A, 116B may operate in separate voltage domains, for example, in power applications, although the scope of this disclosure is not limited as such. The semiconductor die 116A includes a device side 118A, in and/or on which circuitry is formed, and the semiconductor die 116B includes a device side 118B, in and/or on which circuitry is formed. Conductive members 120A extend from the device side 118A toward the multi-layer substrate 104, and conductive members 120B extend from the device side 118B toward the multi-layer substrate 104. Solder joints 122A, 122B couple the conductive members 120A and the conductive members 120B, respectively, to the multi-layer substrate 104, and more specifically, to the top-most metal layer (e.g., metal layer 108) in the multi-layer substrate 104.

In examples in which the semiconductor dies 116A, 116B are in separate voltage domains, the network of metal layers in the multi-layer substrate 104 may preclude electrical communication between the semiconductor dies 116A, 116B.

As briefly mentioned above, the solder joints 106 couple the multi-layer substrate 104 (e.g., one or more metal layers and/or one or more vias in the multi-layer substrate 104) to the conductive terminals 102. The solder joints 106 cover solder joint pillars 214, 216 that extend from the conductive terminals 102 toward the multi-layer substrate 104. The conductive terminals 102 extend from within the semiconductor package 100 to an exterior of the semiconductor package 100, as shown. The conductive terminals 102 are depicted as being gullwing-style terminals, but the scope of this disclosure is not limited as such.

In examples, the solder joint pillars 214, 216 and/or the solder joints 106 may be electrically connected to one or more of the device sides 118A, 118B of the semiconductor dies 116A, 116B via the multi-layer substrate 104.

The solder joints 106 are located at convergence points for multiple different materials, such as solder (e.g., of the solder joints 106), copper (e.g., of the conductive terminals 102), mold compound (e.g., of the mold compound 126), and build-up film (e.g., film 124) of the multi-layer substrate 104. This means that the areas of the solder joints 106 are highly susceptible to delamination, especially during temperature cycling. To mitigate this risk, the solder joint pillars 214, 216 increase the surface area to which the respective solder joints 106 are coupled, thereby increasing adhesion strength between the solder joint 106 and the respective solder joint pillar 214, 216 and decreasing the risk of peeling during temperature cycling (or during field deployment) due to mismatched CTEs between various materials in the semiconductor package 100. For similar reasons, shear stress is also reduced. Further, the solder joint pillar 214, 216 operates as an anchor that mitigates distortion of the solder joint 106 during temperature cycling. By reducing shear stress and solder joint distortion, the risk of solder joint peeling is significantly reduced, thereby substantially increasing manufacturing yield and efficiency, and lowering manufacturing costs.

FIG. 1B is a top-down view of the structure of FIG. 1A, in accordance with various examples. FIG. 1C is a perspective view of the structure of FIG. 1A, in accordance with various examples.

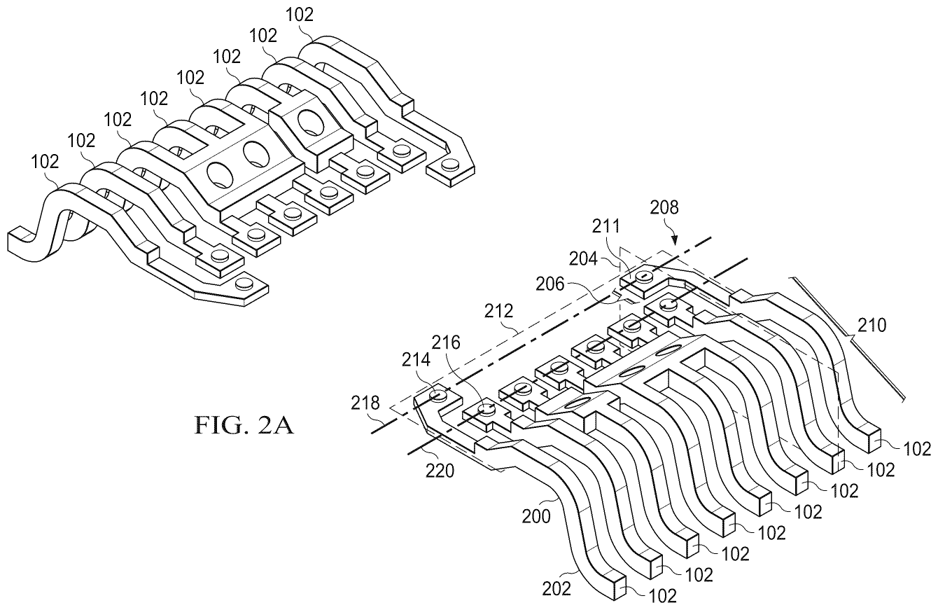

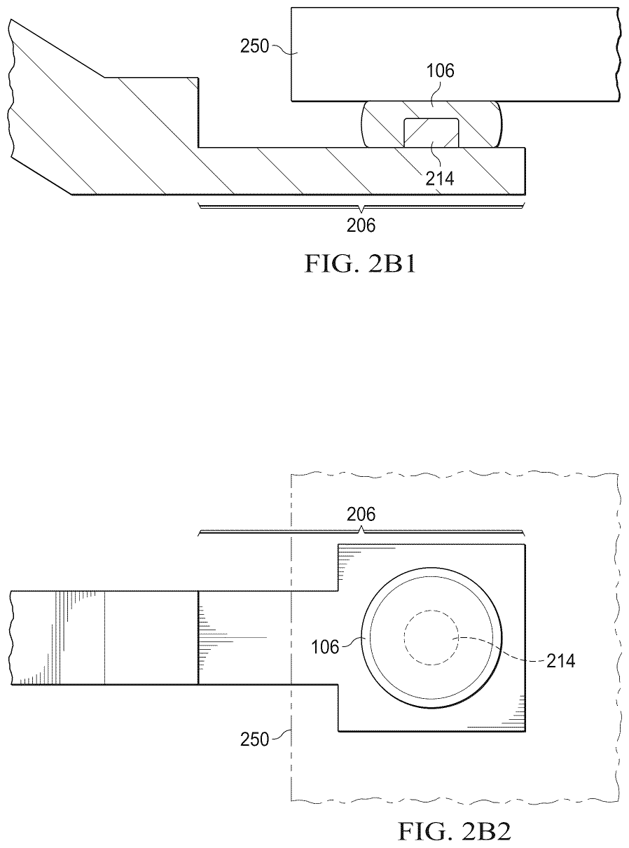

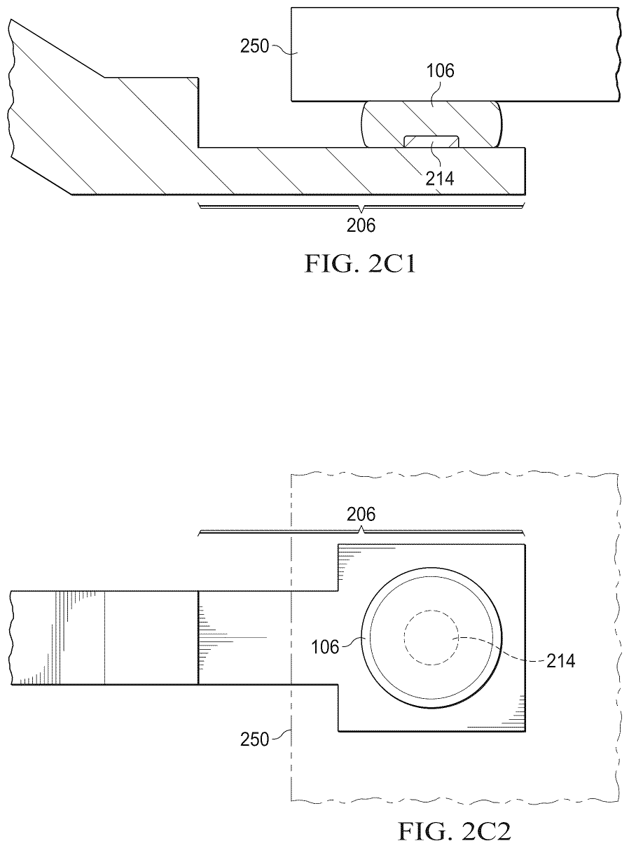

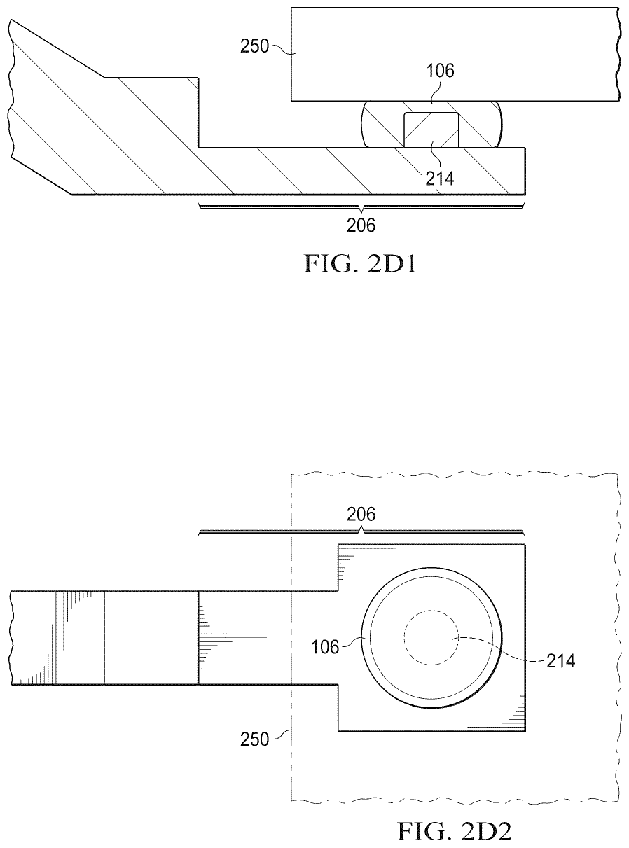

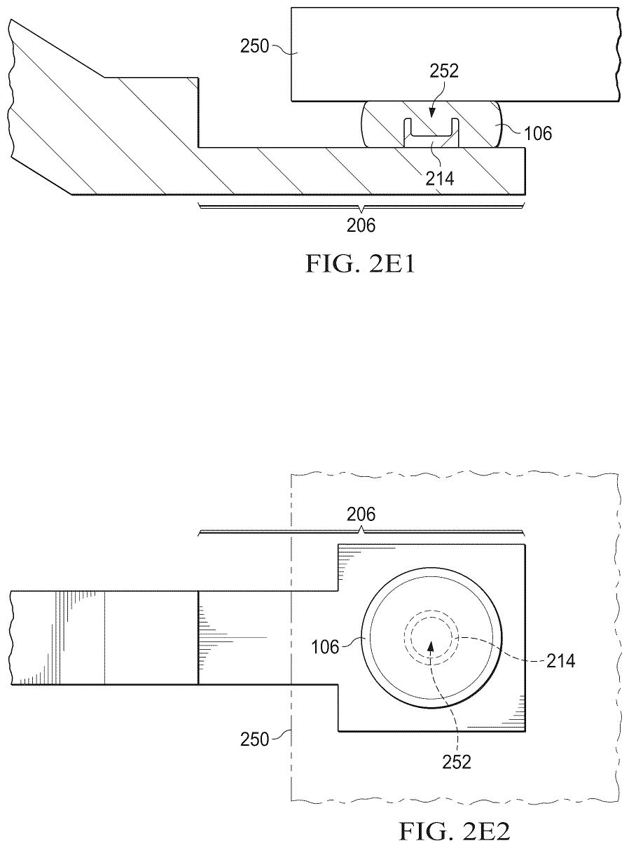

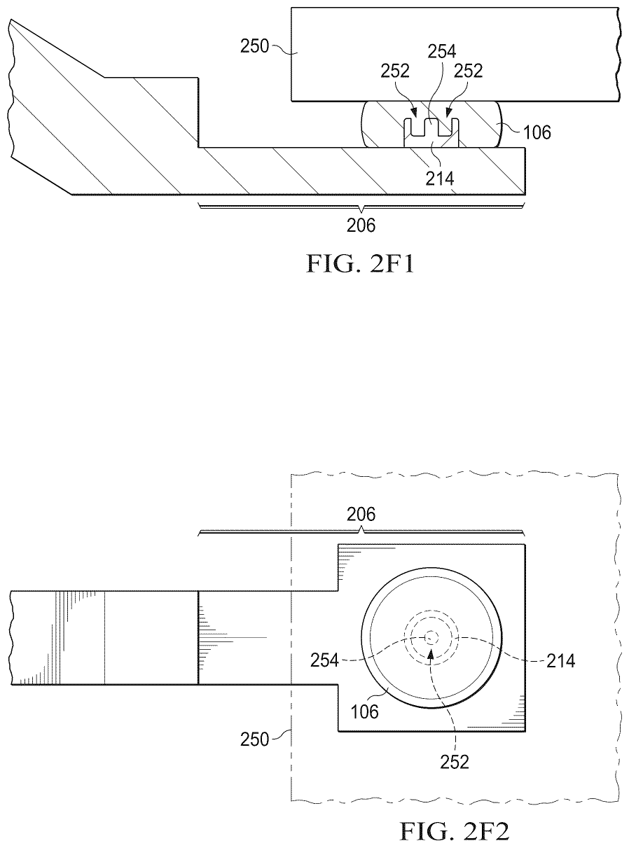

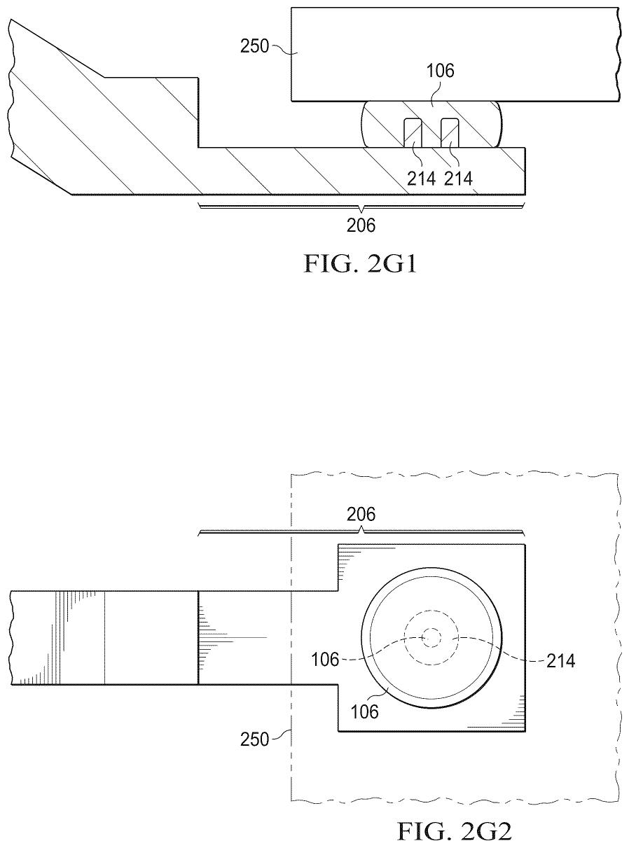

FIGS. 2A-2G2 are perspective and profile cross-sectional views of conductive terminals in a semiconductor package with solder joint pillars, in accordance with various examples. In particular, FIG. 2A is a perspective view of multiple conductive terminals 102, in accordance with various examples. FIG. 2A depicts two sets of conductive terminals 102, although any number of sets of conductive terminals 102 may be included. Because the sets of conductive terminals 102 shown in FIG. 2A are similar or identical, only one set of conductive terminals 102 is expressly described. Each conductive terminal 102 is depicted as having a gullwing-style shape with bends 200 and 202, although the scope of this disclosure is not limited as such. Each conductive terminal 102 lies in its own vertical plane 204, a representative example of which is shown in FIG. 2A. In examples, the conductive terminals 102 on opposing ends of each set of conductive terminals 102 includes multiple segments: a segment 210, which may include bends 200, 202 and be at least in part shaped like the remaining conductive terminals 102 in the set of conductive terminals 102, and which may extend approximately parallel to the remaining conductive terminals 102; a segment 206, which is a terminus of the conductive terminal 102; and a curved segment 208 coupling the segments 206 and 210 to each other. The segments 206 and 208 at least partially lie in a horizontal plane 212. The vertical planes 204 and the horizontal plane 212 are approximately orthogonal to each other. The curvature of the curved segment 208 and the position of the segment 206 are such that the vertical plane 204 of the conductive terminal 102 immediately adjacent the segments 206, 208 coincides with the segment 206, with that vertical plane 204 having a horizontal thickness not exceeding the width of the respective conductive terminal 102.

The segment 206 has a surface 211. A solder joint pillar 214 extends away from the surface 211, as shown. Similarly, each of the conductive terminals 102 includes a solder joint pillar 214 extending away from a surface of that respective conductive terminal 102. The first and last conductive terminals 102 in a set of conductive terminals 102 have solder joint pillars 214 that are aligned such that a line 218 extending through those two solder joint pillars 214 is approximately parallel with a line 220 that extends through the solder joint pillars 214 of the remaining conductive terminals 102 in the set of conductive terminals 102. Each solder joint pillar 214 and its respective conductive terminal 102 are parts of a monolithic structure, meaning that rather than being coupled to its respective conductive terminal 102, each solder joint pillar 214 is formed in conjunction with, and as part of, its respective conductive terminal 102. For example, a solder joint pillar 214 and its respective conductive terminal 102 may be simultaneously stamped, punched, etched, or otherwise formed out of a single piece of metal. The solder joint pillars 214 may have various physical features, some of which are described below, and these physical features enable the technical advantages of the solder joint pillars 214 described herein.

FIG. 2B1 is a profile, cross-sectional view of a portion of a semiconductor package having a solder joint pillar, in accordance with various examples. More specifically, an example solder joint pillar 214 extends away from an example segment 206. A solder joint 106 covers the solder joint pillar 214 and couples to a structure 250. In examples, the structure 250 is the multi-layer substrate 104, and in other examples, the structure 250 is a semiconductor die coupled directly to the solder joint 106 without an intervening substrate (e.g., the multi-layer substrate 104). In FIG. 2B1, the solder joint pillar 214 has a vertical thickness that is between 30% and 80% of the thickness of the solder joint 106 within which the solder joint pillar 214 is located (with the thickness of the solder joint 106 ranging between 60 microns to 70 microns). (Herein, the thickness of a member is measured from the surface from which the member extends.) A vertical thickness in this range is particularly advantageous because the external shear stress applied to the solder joint 106 is substantially and meaningfully reduced relative to thicknesses outside of this range. In addition, the solder joint pillar 214 has an approximately circular cross-sectional shape when viewed from a top-down view, although other cross-sectional shapes, such as rectangles (e.g., squares), triangles, irregular shapes, etc., are included within the scope of this disclosure. In examples, the solder joint pillar 214 has a symmetric cross-sectional shape when viewed from a top-down view. In examples, the solder joint pillar 214 has a polygonal shape when viewed from a top-down view. The solder joint pillar 214 has a maximum cross-sectional width, when viewed from the side as shown in FIG. 2B1, that is between 30% and 40% of the width of the solder joint 106 (with the width or diameter of the solder joint 106 being up to 350 microns, resulting in a maximal cross-sectional width of the solder joint pillar 214 ranging from 105 microns to 140 microns). A maximal width in this range is advantageous because the external shear stress applied to the solder joint 106 is substantially reduced relative to widths outside of this range. FIG. 2B2 is a top view of the structure of FIG. 2B1, in accordance with various examples. In the example of FIGS. 2B1-2B3, as well as in the various other examples described herein, the solder joint pillar 214 may have an inverted trapezoidal cross-sectional shape when viewed from a profile view.

FIG. 2C1 is a profile, cross-sectional view of a portion of a semiconductor package having a solder joint pillar, in accordance with various examples. More specifically, the example solder joint pillar 214 extends away from the example segment 206. A solder joint 106 covers the solder joint pillar 214 and couples to the structure 250. In examples, the structure 250 is the multi-layer substrate 104, and in other examples, the structure 250 is a semiconductor die coupled directly to the solder joint 106 without an intervening substrate (e.g., the multi-layer substrate 104). In FIG. 2C1, the solder joint pillar 214 has a vertical thickness that is within the range described above with respect to FIG. 2B1, with the same attendant advantages and disadvantages of being within or outside this range. In addition, the solder joint pillar 214 has an approximately circular cross-sectional shape when viewed from above, although other cross-sectional shapes, such as rectangles (e.g., squares), triangles, irregular shapes, etc., are included within the scope of this disclosure. In examples, the solder joint pillar 214 has a symmetric cross-sectional shape when viewed from a top-down view. In examples, the solder joint pillar 214 has a polygonal shape when viewed from a top-down view. The solder joint pillar 214 has a maximum cross-sectional width that is within the range described above with respect to FIG. 2B1, with the same attendant advantages and disadvantages of being within or outside this range. FIG. 2C2 is a top view of the structure of FIG. 2C1, in accordance with various examples.

FIG. 2D1 is a profile, cross-sectional view of a portion of a semiconductor package having a solder joint pillar, in accordance with various examples. More specifically, the example solder joint pillar 214 extends away from the example segment 206. A solder joint 106 covers the solder joint pillar 214 and couples to the structure 250. In examples, the structure 250 is the multi-layer substrate 104, and in other examples, the structure 250 is a semiconductor die coupled directly to the solder joint 106 without an intervening substrate (e.g., the multi-layer substrate 104). In FIG. 2D1, the solder joint pillar 214 has a vertical thickness that is within the range described above with respect to FIG. 2B1, with the same attendant advantages and disadvantages of being within or outside this range. In addition, the solder joint pillar 214 has an approximately circular cross-sectional shape when viewed from above, although other cross-sectional shapes, such as rectangles (e.g., squares), triangles, irregular shapes, etc., are included within the scope of this disclosure. In examples, the solder joint pillar 214 has a symmetric cross-sectional shape when viewed from a top-down view. In examples, the solder joint pillar 214 has a polygonal shape when viewed from a top-down view. The solder joint pillar 214 has a maximum cross-sectional width that is within the range described above with respect to FIG. 2B1, with the same attendant advantages and disadvantages of being within or outside this range. FIG. 2D2 is a top view of the structure of FIG. 2D1, in accordance with various examples.

FIG. 2E1 is a profile, cross-sectional view of a portion of a semiconductor package having a solder joint pillar, in accordance with various examples. More specifically, the example solder joint pillar 214 extends away from the example segment 206. A solder joint 106 covers the solder joint pillar 214 and couples to the structure 250. In examples, the structure 250 is the multi-layer substrate 104, and in other examples, the structure 250 is a semiconductor die coupled directly to the solder joint 106 without an intervening substrate (e.g., the multi-layer substrate 104). In FIG. 2E1, the solder joint pillar 214 includes a cavity 252. The walls of the cavity 252 may intersect at right angles, approximately right angles, or at curved surfaces (the latter being shown in FIG. 2E1). The thickness of the solder joint pillar 214 within the cavity 252 ranges from 10% and 50% of the thickness of the solder joint 106, and the thickness of the solder joint pillar 214 outside of the cavity 252 is within the range described above with respect to FIG. 2B1, with the same attendant advantages and disadvantages of being within or outside of these ranges. The solder joint pillar 214 has a maximum cross-sectional width that is within the range described above with respect to FIG. 2B1, with the same attendant advantages and disadvantages of being within or outside this range. FIG. 2E2 is a top view of the structure of FIG. 2E1, in accordance with various examples.

FIG. 2F1 is a profile, cross-sectional view of a portion of a semiconductor package having a solder joint pillar, in accordance with various examples. More specifically, the example solder joint pillar 214 extends away from the example segment 206. A solder joint 106 covers the solder joint pillar 214 and couples to the structure 250. In examples, the structure 250 is the multi-layer substrate 104, and in other examples, the structure 250 is a semiconductor die coupled directly to the solder joint 106 without an intervening substrate (e.g., the multi-layer substrate 104). In FIG. 2F1, the solder joint pillar 214 includes a cavity 252. The cavity 252 circumscribes a protruding member 254. The walls of the cavity 252 may intersect at right angles, approximately right angles, or at curved surfaces (a combination of which is shown in FIG. 2F1). The thickness of the solder joint pillar 214 within the cavity 252 ranges from 10% to 50% of the thickness of the solder joint 106, and the thickness of the solder joint pillar 214 outside of the cavity 252 is within the range described above with respect to FIG. 2B1, with the same attendant advantages and disadvantages of being within or outside of these ranges. The solder joint pillar 214 has a maximum cross-sectional width, when viewed from the side as shown in FIG. 2F1, that is within the range described above with respect to FIG. 2B1, with the same attendant advantages and disadvantages of being within or outside this range. FIG. 2F2 is a top view of the structure of FIG. 2F1, in accordance with various examples.

FIG. 2G1 is a profile, cross-sectional view of a portion of a semiconductor package having a solder joint pillar, in accordance with various examples. More specifically, the example of FIG. 2G1 includes two solder joint pillars 214 extending away from the example segment 206. The thicknesses of the two solder joint pillars 214 may be the same as those in the various examples described above, and the maximal width of each of the solder joint pillars 214 ranges from 10% and 40% of the width of the solder joint 106 (with widths inside this range being advantageous because the external shear stress applied to the solder joint 106 is substantially lower than it would be for widths outside of this range), which covers the solder joint pillars 214 and couples to the structure 250. FIG. 2G2 is a top view of the structure of FIG. 2G1, in accordance with various examples.

Descriptions of the solder joint pillars 214 with respect to FIGS. 2A1-2G2 also apply to the solder joint pillars 216 (e.g., in FIG. 2A), and vice versa.

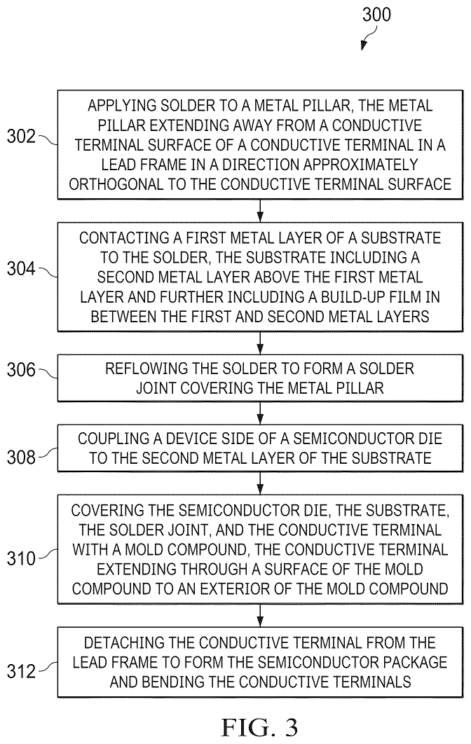

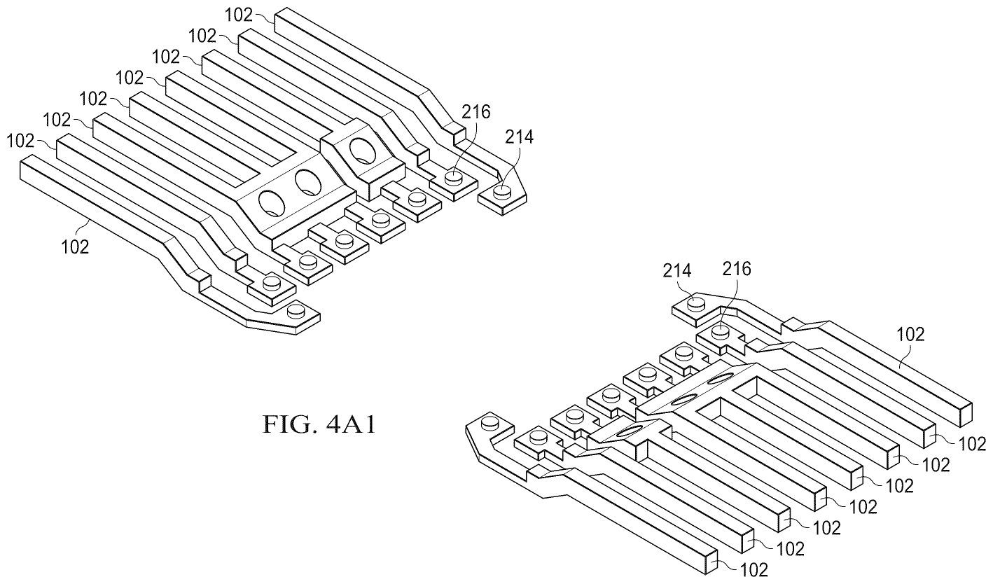

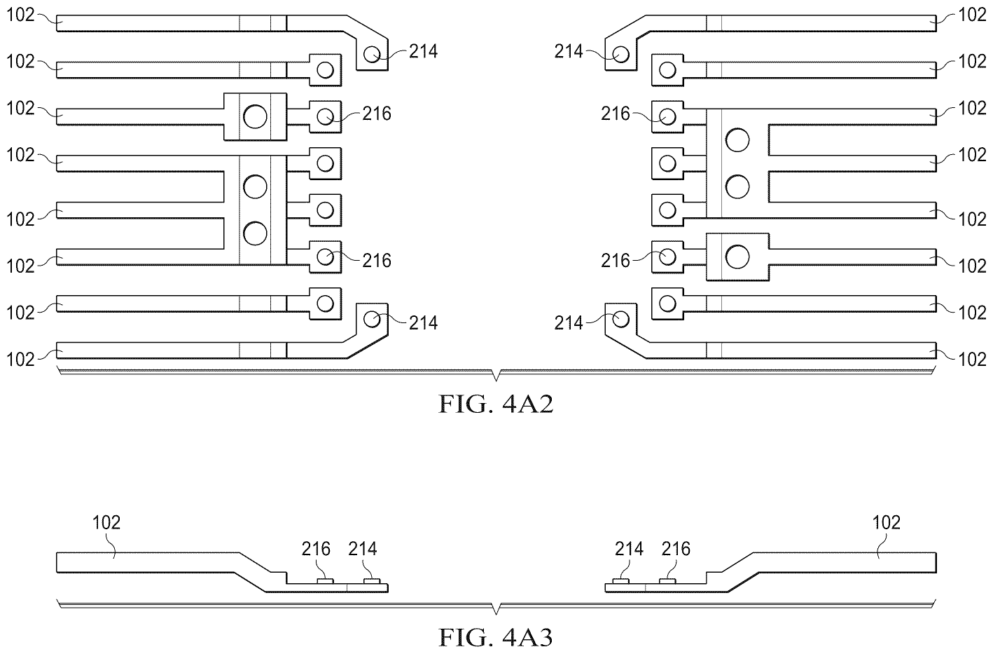

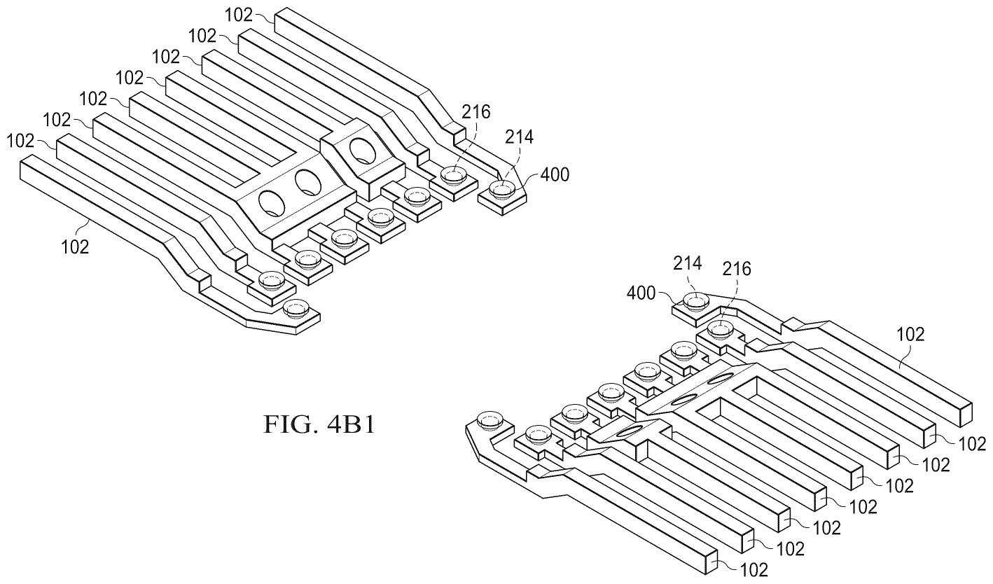

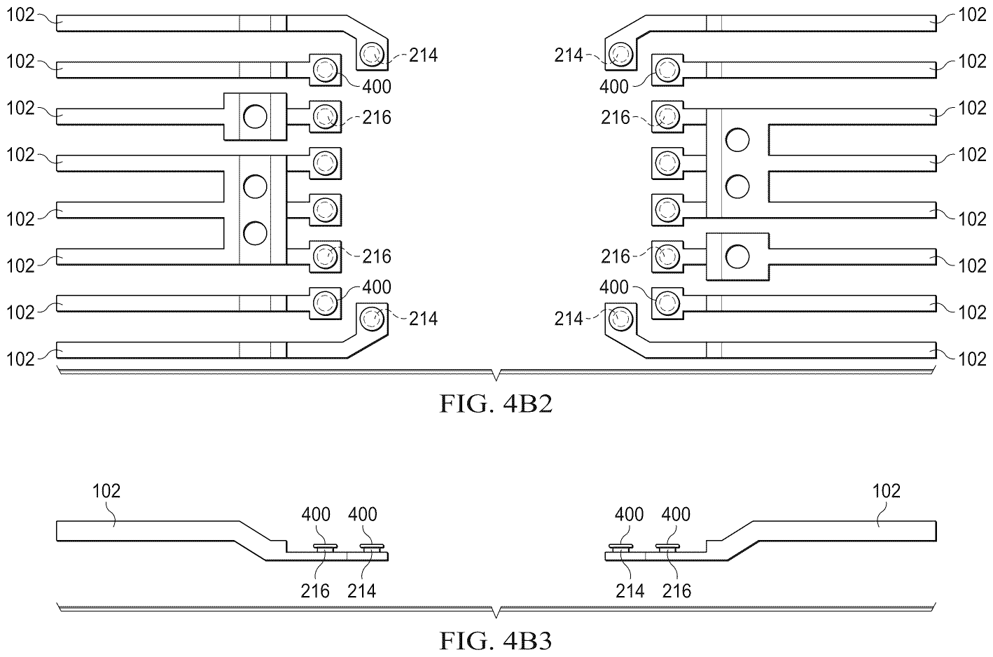

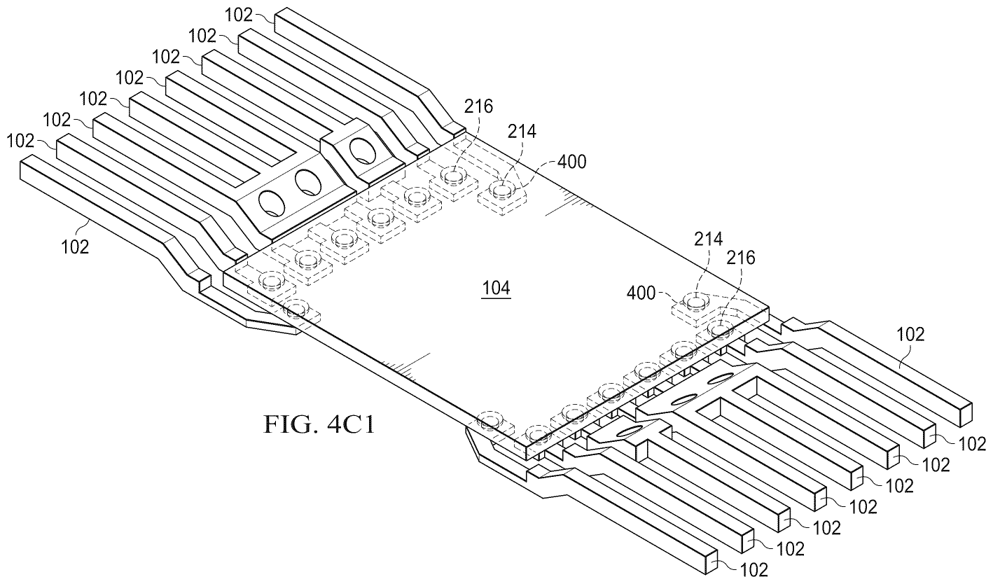

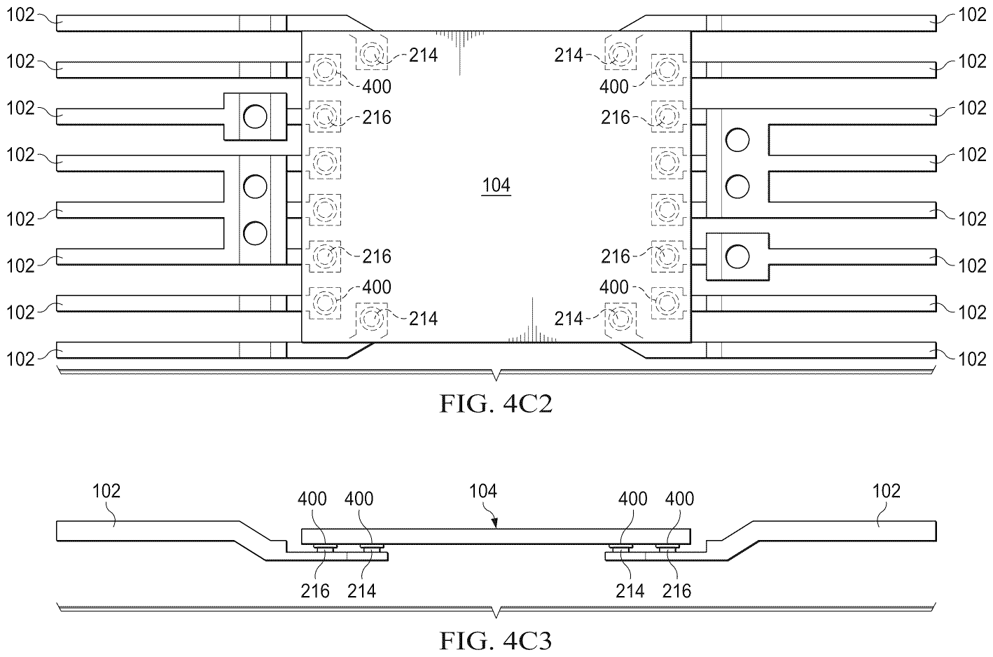

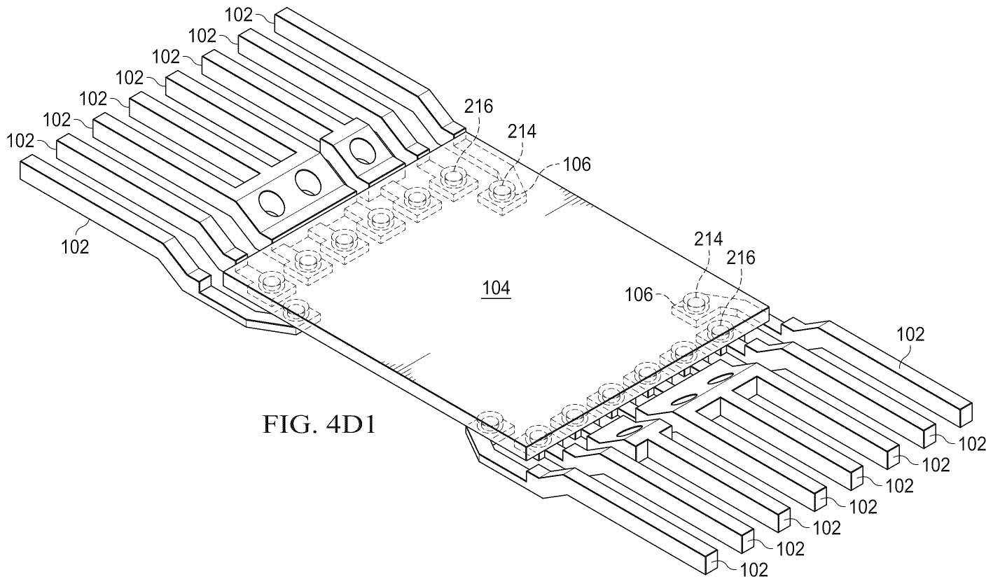

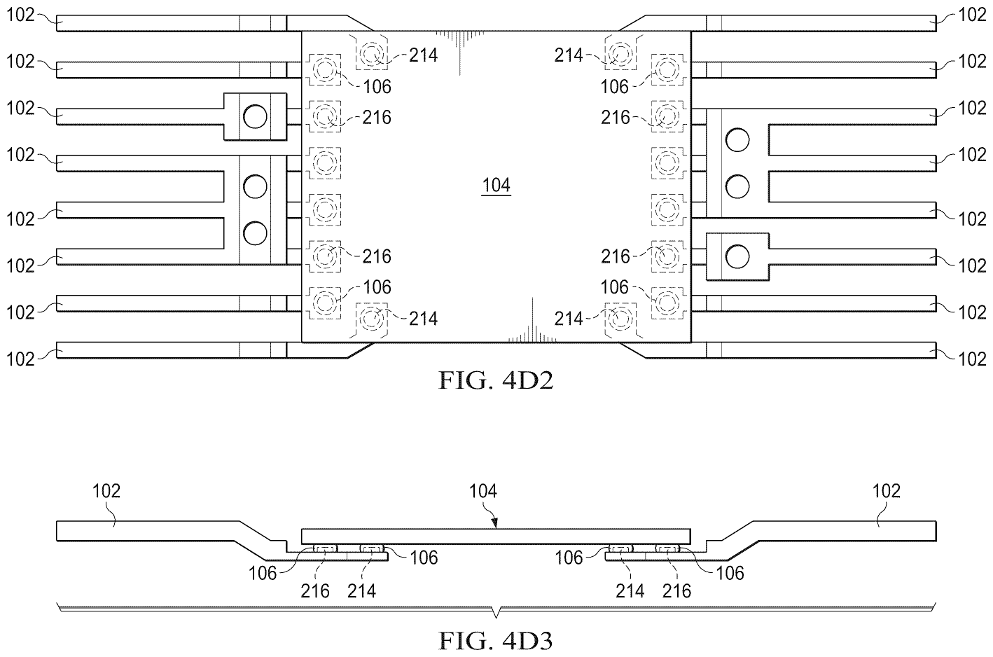

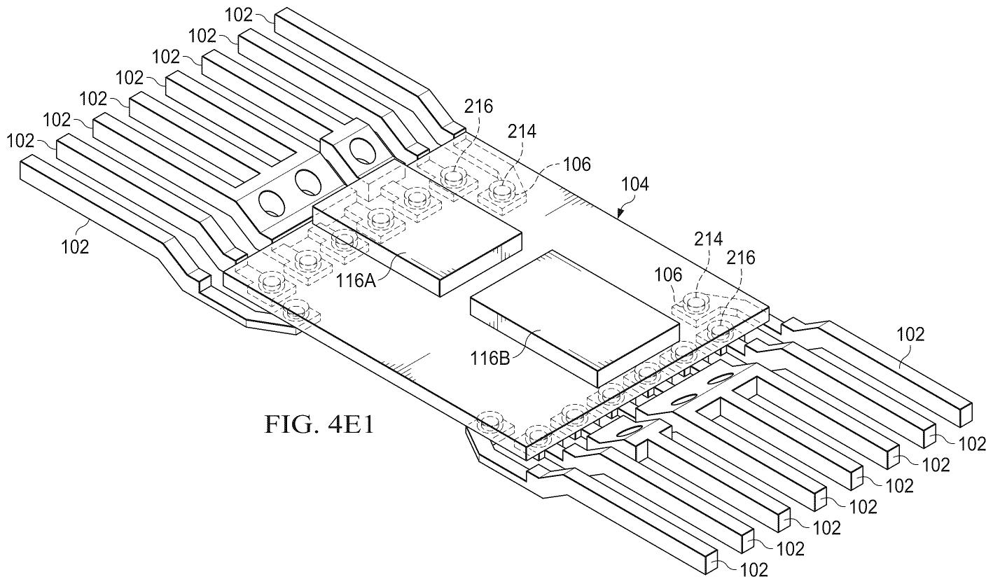

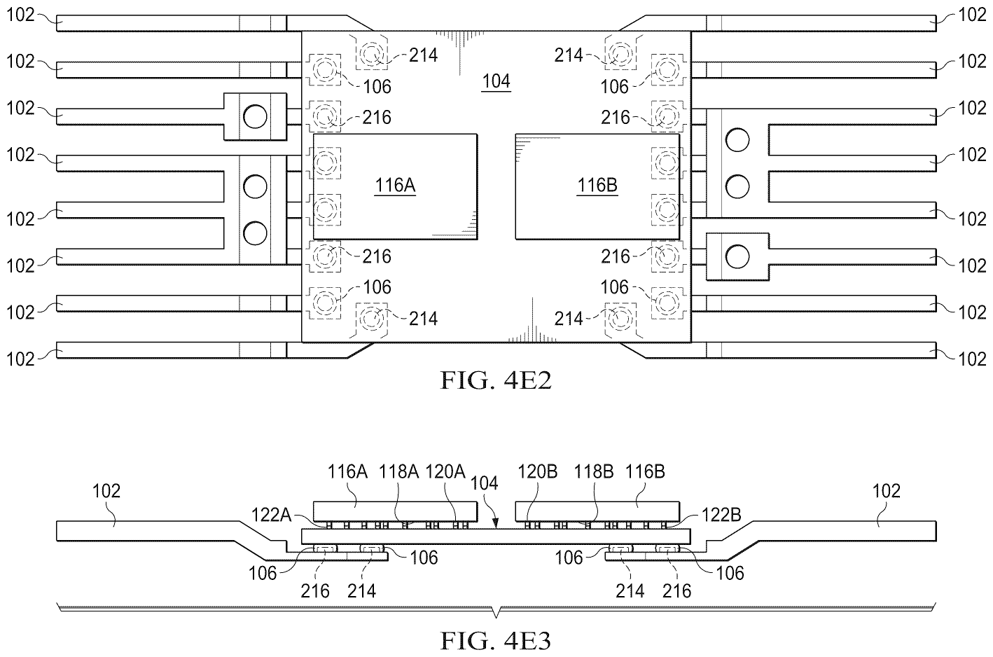

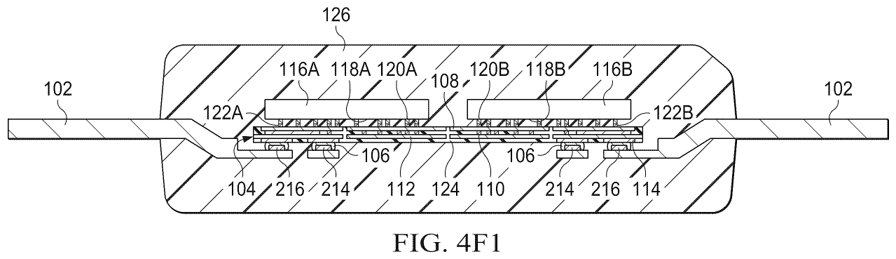

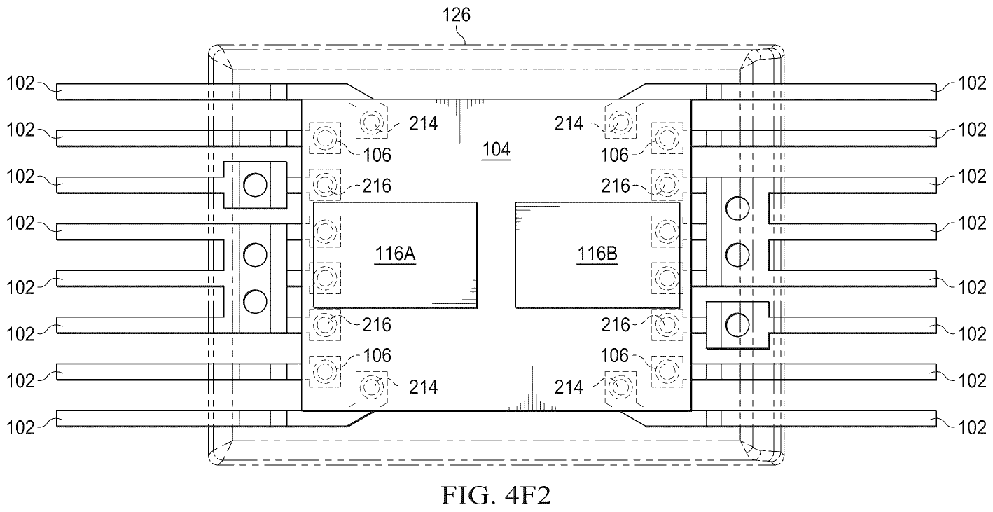

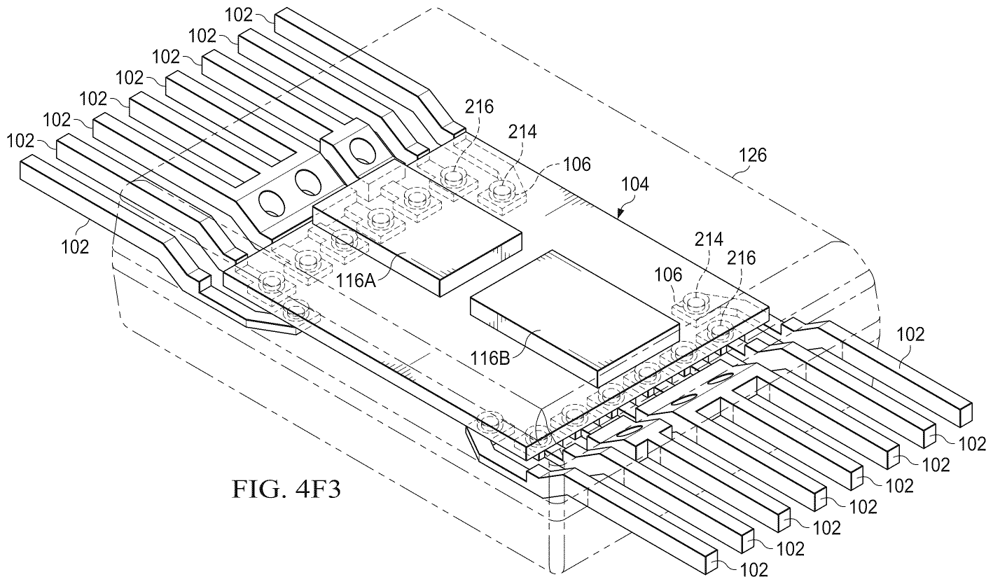

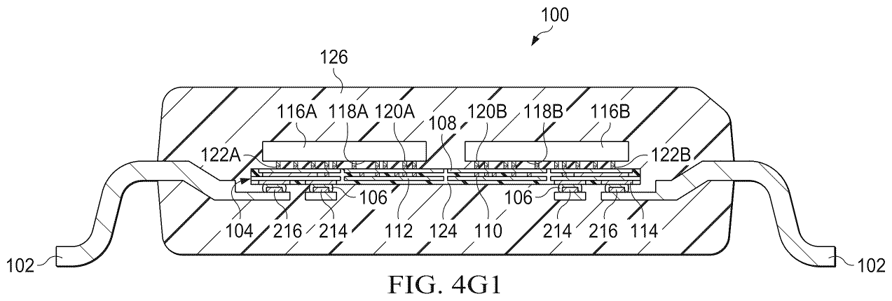

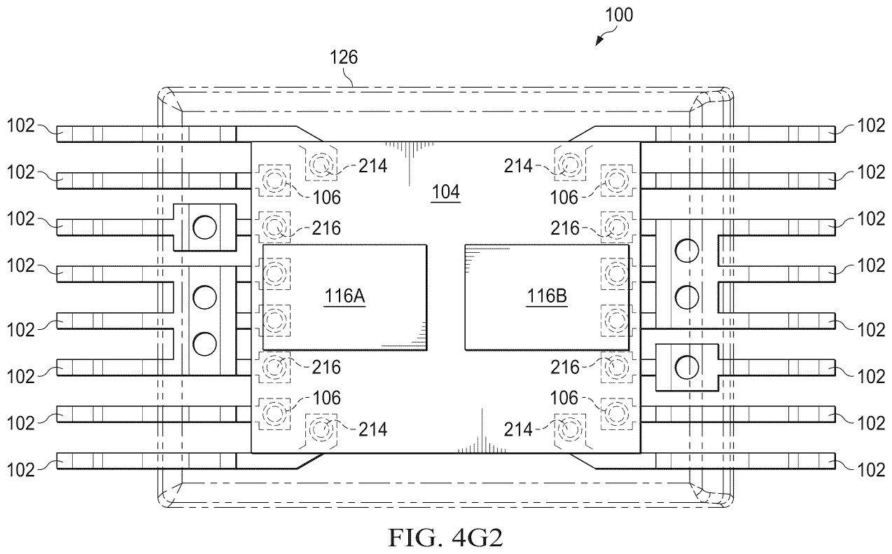

FIG. 3 is a flow diagram of a method 300 for manufacturing a semiconductor package having solder joint pillars, in accordance with various examples. For example, the method 300 is useful to manufacture any of the examples described with reference to FIGS. 1A-2G. FIGS. 4A1-4G3 are a process flow for manufacturing a semiconductor package having solder joint pillars, in accordance with various examples. Accordingly, the method 300 and the process flow of FIGS. 4A1-4G3 are now described in parallel.

The method 300 begins with applying solder to a metal pillar, with the metal pillar extending away from a conductive terminal surface of a conductive terminal in a lead frame in a direction approximately orthogonal to the conductive terminal surface (302). FIG. 4A1 is a perspective view of a portion of a lead frame, with FIG. 4A2 being a top-down view of the structure of FIG. 4A1, and with FIG. 4A3 being a perspective view of the structure of FIG. 4A1, in accordance with various examples. The portion of the lead frame shown in FIGS. 4A1-4A3 is similar or identical to that shown in FIG. 2A and described above and includes the solder joint pillars 214, 216, except that the conductive terminals 102 are still flat and not yet bent. The solder joint pillars are interchangeably referred to herein as metal pillars. Solder is applied (e.g., deposited, printed, etc.) on or near the metal pillars 214, 216 per step 302, as FIG. 4B1 shows with the application of the solder bumps 400. FIG. 4B2 is a top-down view of the structure of FIG. 4B1, and FIG. 4B3 is a perspective view of the structure of FIG. 4B1, in accordance with various examples.

Although not expressly shown in the process flow of FIGS. 4A1-4G3, the structures of FIGS. 4A1-4G3 may be attached to other, similar structures during the manufacturing process. For example, the conductive terminals shown in FIG. 4A1 may be coupled to a larger lead frame that includes additional such conductive terminals, as semiconductor packages may be manufactured at mass scale. Similarly, in FIGS. 4F1-4F3 (described below), only individual molded packages are shown, but in practice, the molded packages may actually be coupled to long strips of molded packages formed in a mold chase, which are subsequently singulated by sawing through the mold compound and trimming the lead frame to produce individual conductive terminals.

The method 300 includes contacting a first metal layer of a substrate to the solder, with the substrate including a second metal layer above the first metal layer and further including a build-up film in between the first and second metal layers (304). FIG. 4C1 is a perspective view of a multi-layer substrate 104 being coupled to the solder bumps 400. The multi-layer substrate 104, as described above, includes multiple metal layers and a build-up film (e.g., ABF) contacting the multiple metal layers. At least one of the metal layers contacts the solder bumps 400, thereby providing electrical connectivity between the solder bumps 400 and the network of metal layers within the multi-layer substrate 104. FIG. 4C2 is a top-down view of the structure of FIG. 4C1, and FIG. 4C3 is a profile view of the structure of FIG. 4C1, in accordance with various examples.

The method 300 includes reflowing the solder to form a solder joint covering the metal pillar (306). FIG. 4D1 is a perspective view of the structure of FIG. 4C1, except that the solder bumps 400 have been reflowed to form the solder joints 106 described herein. When reflowed, the solder bumps 400 flow to cover the solder joint pillars 214, 216. For example, the solder joints 106 formed by reflow of the solder bumps 400 may cover solder joint pillars 214, 216 as shown in the examples of FIGS. 2B1-2G2. The amount, position, and method of application of the solder bumps 400 may be adjusted to control the resulting physical features of the solder joints 106 and the underlying solder joint pillars 214, 216, for example, to obtain the physical features described above with reference to FIGS. 2B1-2G2. For instance, the amount of solder in the solder bumps 400 affects the resulting thickness of the solder joints 106. FIG. 4D2 is a top view of the structure of FIG. 4D1, in accordance with various examples. FIG. 4D3 is a profile view of the structure of FIG. 4D1, in accordance with various examples.

The method 300 comprises coupling a device side of a semiconductor die to the second metal layer of the substrate (308). FIG. 4E1 is a perspective view depicting the semiconductor dies 116A, 116B coupled to the multi-layer substrate 104, and more particularly, to a metal layer (e.g., a topmost metal layer) in the multi-layer substrate 104. In examples, solder bumps may be useful to establish the connections between the semiconductor dies 116A, 116B and the multi-layer substrate 104. As described above, the semiconductor dies 116A, 116B may be in separate voltage domains, although the scope of this disclosure is not limited as such. Furthermore, although two semiconductor dies are depicted, any number of semiconductor dies (e.g., one or more dies) may be coupled to the multi-layer substrate 104. FIG. 4E2 is a top-down view of the structure of FIG. 4E1, in accordance with various examples. FIG. 4E3 is a profile view of the structure of FIG. 4E1, in accordance with various examples.

The method 300 comprises covering the semiconductor die, the substrate, the solder joint, and the conductive terminal with a mold compound, with the conductive terminal extending through a surface of the mold compound to an exterior of the mold compound (310). FIG. 4F1 is a profile, cross-sectional view of the example structure of FIG. 4E1, but with the mold compound 126 applied to the structure. The mold compound 126 may be applied by any suitable technique, such as a mold injection technique using a mold chase. The conductive terminals 102 are still flat and not yet bent, as shown. FIG. 4F2 is a top-down view of the structure of FIG. 4F1, in accordance with various examples. FIG. 4F3 is a perspective view of the structure of FIG. 4F1, in accordance with various examples.

The method 300 comprises detaching the conductive terminal from the lead frame to form the semiconductor package and bending the conductive terminals (312). FIG. 4G1 is a profile cross-sectional view of the structure of FIG. 4F1, except that the mold compound has been singulated (e.g., sawn) to produce the individual semiconductor package 100 of FIG. 4G1, the lead frame has been trimmed to produce the individual conductive terminals 102, and the conductive terminals 102 have been bent to have a gullwing-style shape, as shown. FIG. 4G2 is a top-down view of the structure of FIG. 4G1, in accordance with various examples. FIG. 4G3 is a perspective view of the structure of FIG. 4G1, in accordance with various examples.

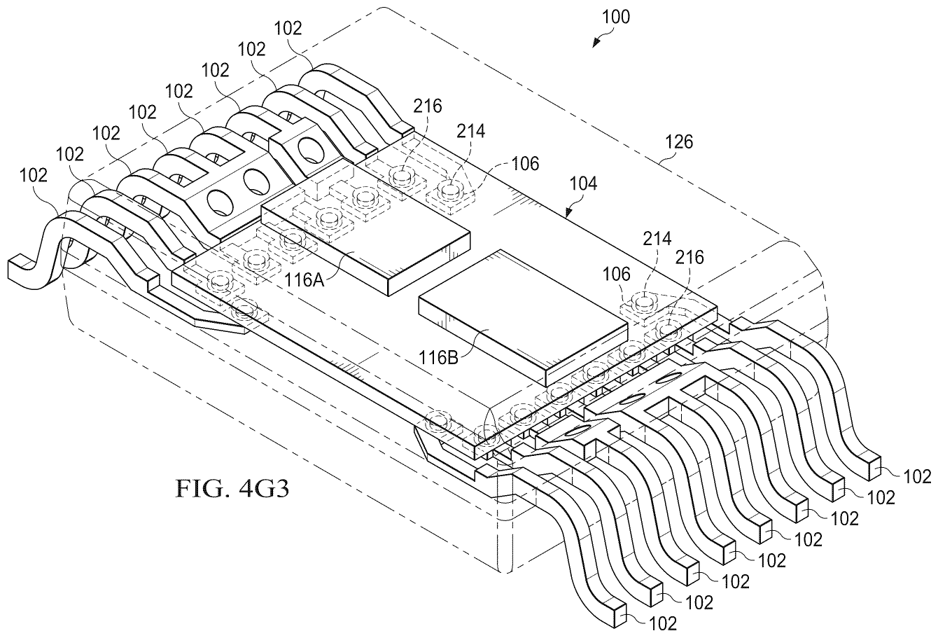

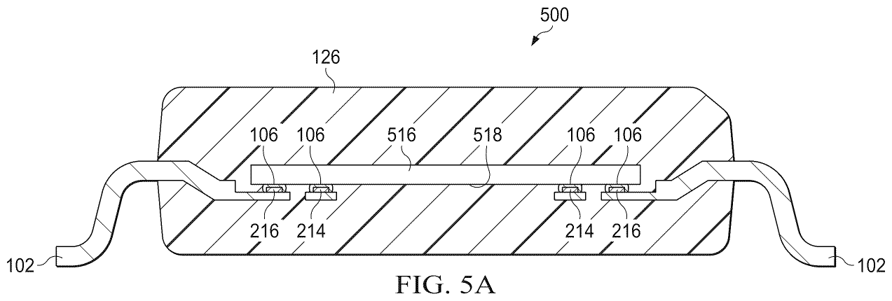

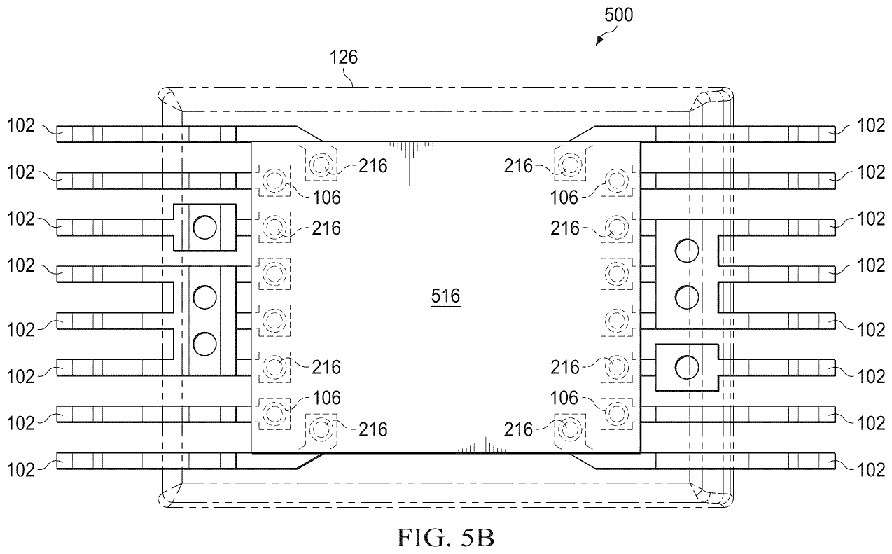

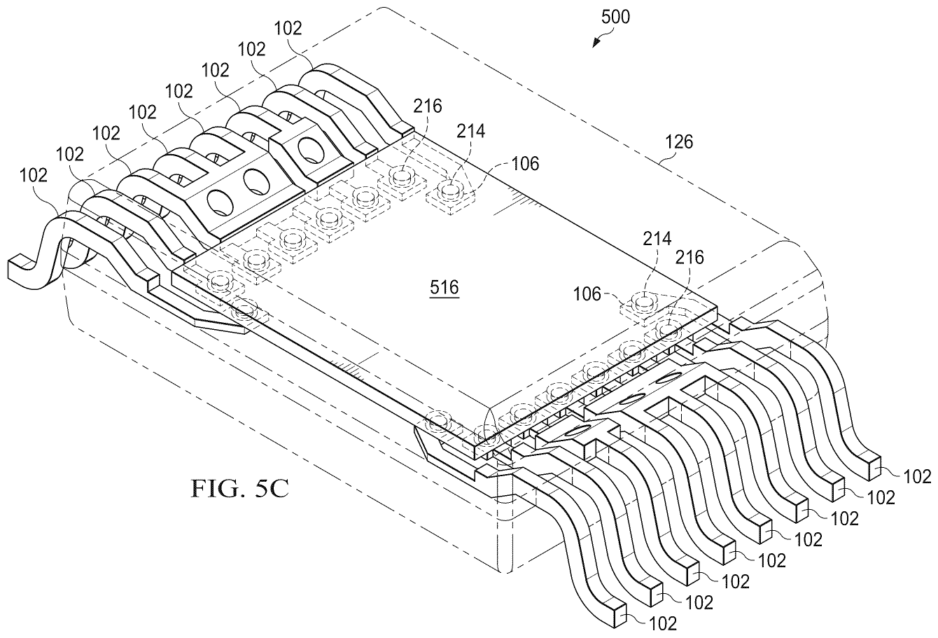

The foregoing examples include the multi-layer substrate 104 as an intermediary between the semiconductor dies 116A, 116B and the conductive terminals 102. However, in some examples, the multi-layer substrate 104 may be omitted and a semiconductor die may be coupled directly to the conductive terminals 102 using solder joint pillars covered by solder joints as described herein (i.e., omitting a die pad). FIG. 5A is a profile cross-sectional view of an example semiconductor package 500 which is virtually identical to the semiconductor package 100 shown in FIG. 1A, except that a single semiconductor die 516 has a device side 518 that is electrically connected to the conductive terminals 102 by solder joints 106 that cover solder joint pillars 214, 216. The solder joint pillars 214, 216 provide the technical advantages described herein and thus are not described in greater detail here. FIG. 5B is a top-down view of the structure of FIG. 5A, in accordance with various examples. FIG. 5C is a perspective view of the structure of FIG. 5A, in accordance with various examples.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In this description, unless otherwise stated, “about,” “approximately” or “substantially” preceding a parameter means being within +/−10 percent of that parameter. Modifications are possible in the described examples, and other examples are possible within the scope of the claims.

What is claimed is:

1. A semiconductor package, comprising:
a semiconductor die having a device side in which circuitry is formed;
a multi-layer substrate having multiple metal layers and a build-up film in between and contacting the multiple metal layers, the device side of the semiconductor die coupled to at least one of the multiple metal layers of the multi-layer substrate;
a first solder joint electrically connected to the device side of the semiconductor die via the multi-layer substrate;
a gullwing-shaped first conductive terminal coupled to the first solder joint, the first conductive terminal having a first conductive terminal surface including a first metal pillar covered by the first solder joint;
a second solder joint electrically connected to the device side of the semiconductor die via the multi-layer substrate;
a gullwing-shaped second conductive terminal coupled to the second solder joint, the second conductive terminal having first and second segments, the first segment including a second conductive terminal surface comprising a second metal pillar covered by the second solder joint, and the second segment extending approximately parallel to the first conductive terminal, the second metal pillar coinciding with a vertical plane in which the first conductive terminal sits, the first and second segments coupled by a curved segment that lies in a horizontal plane approximately orthogonal to the vertical plane; and
a mold compound covering the semiconductor die, the first and second solder joints, and the first and second conductive terminals, the first and second conductive terminals extending outside of the mold compound through a surface of the mold compound.

2. The semiconductor package of claim 1, the first metal pillar having a vertical thickness that is between 30% and 80% of a vertical thickness of the first solder joint, the thicknesses of the first metal pillar and the first solder joint measured from the first conductive terminal surface.

3. The semiconductor package of claim 1, wherein the first metal pillar has a maximal cross-sectional width, as viewed in a profile view, ranging from 105 microns to 140 microns.

4. The semiconductor package of claim 1, wherein the first solder joint has a vertical thickness ranging from 60 microns to 70 microns.

5. The semiconductor package of claim 1, further comprising a second semiconductor die coupled to the multi-layer substrate, and wherein the semiconductor die and the second semiconductor die are configured to operate in different voltage domains.

6. The semiconductor package of claim 1, wherein the multi-layer substrate is not a printed circuit board (PCB).

7. The semiconductor package of claim 1, wherein each of the gullwing-shaped first and second conductive terminals includes a first segment proximal to the mold compound that is elevated relative to a second segment distal to the mold compound.

8. A method for manufacturing a semiconductor package, comprising:
applying solder to a metal pillar, the metal pillar extending away from a conductive terminal surface of a conductive terminal in a lead frame in a direction approximately orthogonal to the conductive terminal surface;
contacting a first metal layer of a multi-layer substrate to the solder, the multi-layer substrate including a second metal layer above the first metal layer and further including a build-up film in between the first and second metal layers;
reflowing the solder to form a solder joint covering the metal pillar;
coupling a device side of a semiconductor die to the second metal layer of the multi-layer substrate;
covering the semiconductor die, the multi-layer substrate, the solder joint, and the conductive terminal with a mold compound, the conductive terminal extending through a surface of the mold compound to an exterior of the mold compound; and
detaching the conductive terminal from the lead frame to form the semiconductor package.

9. The method of claim 8, wherein the metal pillar has a maximal cross-sectional width, from a profile view, ranging from 105 microns to 140 microns.

10. The method of claim 8, wherein the metal pillar has a vertical thickness that is between 30% and 80% of a height of the solder joint.

11. The method of claim 10, wherein the height of the solder joint ranges from 60 microns to 70 microns.

12. The method of claim 8, further comprising manufacturing the multi-layer substrate by:
plating one of the first and second metal layers to produce a plated metal layer;
depositing the build-up film on the plated metal layer;
grinding the deposited build-up film; and
plating the other of the first and second metal layers on the grinded build-up film.

13. A semiconductor package, comprising:
a semiconductor die having a device side in which circuitry is formed;
a multi-layer substrate having multiple metal layers and a build-up film in between and contacting the multiple metal layers, the device side of the semiconductor die coupled to at least one of the multiple metal layers of the multi-layer substrate;
a solder joint coupled to one or more of the multiple metal layers of the multi-layer substrate;
a conductive terminal coupled to the solder joint, the conductive terminal having a conductive terminal surface including a metal pillar extending into the solder joint, the metal pillar having a symmetric shape in a top view, wherein the metal pillar and the conductive terminal are parts of a monolithic structure; and
a mold compound covering the semiconductor die, the multi-layer substrate, the solder joint, and the conductive terminal, the conductive terminal extending outside of the mold compound through a lateral surface of the mold compound.

14. The semiconductor package of claim 13, wherein the metal pillar is the sole metal pillar covered by the solder joint.

15. The semiconductor package of claim 13, wherein the metal pillar has a vertical thickness that is between 30% and 80% of a vertical thickness of the solder joint, the vertical thicknesses of the metal pillar and the solder joint measured from the conductive terminal surface.

16. The semiconductor package of claim 15, wherein the vertical thickness of the solder joint ranges from 60 microns to 70 microns.

17. The semiconductor package of claim 13, wherein the solder joint contacts multiple materials having differing coefficients of thermal expansion (CTE).

18. The semiconductor package of claim 17, wherein the multiple materials include copper, the build-up film, and the mold compound.

19. The semiconductor package of claim 13, wherein the metal pillar has a maximal cross-sectional width, when viewed in a profile view, ranging from 105 microns to 140 microns.

20. The semiconductor package of claim 13, wherein the semiconductor die is not coupled to a die pad.

21. The semiconductor package of claim 13, wherein, in a top view, the metal pillar has a shape that is approximately symmetric.

22. The semiconductor package of claim 21, wherein the shape is circular or polygonal.

23. The semiconductor package of claim 13, wherein, in a cross-sectional side view, the metal pillar has an inverted trapezoidal shape.

24. A semiconductor package, comprising:
a semiconductor die having a device side in which circuitry is formed;
a solder joint coupled directly to the device side of the semiconductor die;
a conductive terminal coupled directly to the solder joint, the conductive terminal having a conductive terminal surface including a metal pillar extending into the solder joint, the metal pillar having a symmetric shape in a top view, wherein the metal pillar and the conductive terminal are parts of a monolithic structure; and
a mold compound covering the semiconductor die, the solder joint, and the conductive terminal, the conductive terminal extending outside of the mold compound through a lateral surface of the mold compound.
